(19) United States
(12) Patent Application Publication
(10) Pub. No.: US 2004/0005010 A1
(43) Pub. Date: Jan. 8, 2004

(54) Channel estimator and equalizer for OFDM systems

(75) Inventors: Ping He, Singapore (SG); Chin Keong Ho, Singapore (SG); Sumei Sun, Singapore (SG)

Correspondence Address: MERCHANT & GOULD PC, P.O. BOX 2903, MINNEAPOLIS, MN, 55402-0903, US

(73) Assignee: National University of Singapore, Singapore (SG)

(21) Appl. No.: 10/190,330

(22) Filed: Jul. 5, 2002

(51) Int. Cl. H03H 7/30; H03H 7/40; H04K 1/10; H04L 27/28; H03K 5/159

(52) U.S. Cl. 375/260; 375/232

(57) ABSTRACT

An initial estimate of the channel response in an OFDM system is obtained. An implied ICI is calculated using an estimated frequency offset, and used to adjust output from an FFT in an OFDM receiver. The channel response is iteratively estimated one or more times using this procedure. Data equalization is performed using the iteratively calculated channel estimate. The implied ICI is constructed, and the output from the FFT in the OFDM receiver is adjusted to determine an estimate of transmitted data. A simplified implementation of iterative channel estimation and data equalization involves adjusting single tap equalizer values to provide an acceptable estimate of incoming data. The simplified iterative channel equalizer can be implemented using a FIR filter.

### FIELD OF THE INVENTION

The preset invention relates to channel estimation and equalization for OFDM systems.

### BACKGROUND

Orthogonal frequency division multiplexing (OFDM), also referred to as multicarrier (MC) modulation, provides near optimum spectrum efficiency (asymptotically Q bit/Hz for 2^{Q}-ary modulation of each subcarrier).

OFDM also provides an excellent ability to combat the effects of severe multipath propagation, co-channel interference and impulsive parasitic noise etc. Consequently, OFDM has been adopted in both wired and wireless applications, including digital audio broadcasting (DAB) and digital video broadcasting (DVB), wireless LAN and Hiperlan2.

In existing OFDM receivers, an equalizer with one tap for each subcarrier is used to estimate the channel response during a training period, and to compensate the following OFDM symbols with the channel estimates.

One of the principal limitations associated with OFDM systems, however, is their sensitivity to frequency offset caused by a mismatch between transmitter and receiver oscillators, Doppler shift, and channel impairments. This limitation arises as OFDM is implemented by performing a transform step involving inverse FFT processing (IFFT) at the transmitter, such that all subcarriers in one OFDM symbol are mutually orthogonal in frequency domain.

Consequently, if a frequency offset exists in the received signal, not only is the signal amplitude attenuated, the orthogonality of all subcarriers in the received signal is also disrupted. The desired signal of one subcarrier is thus disturbed by signals from other subcarriers. This phenomenon is referred as intercarrier interference (ICI), which can degrade severely the accuracy of the channel equalization when the one tap equalizer is used. In such cases, more sophisticated equalizes are desirably considered.

Mathematical Model

A discrete-time baseband equivalent model of the OFDM system is schematically represented in FIGS. 1 and 2. These schematic representations are described briefly in overview directly below.

FIG. 1 schematically represents a transmitter, and FIG. 2 schematically represents a receiver. FIG. 1 depicts an OFDM transmitter in which input is provided to a serial-to-parallel converter 110, the output of which is passed to an inverse Fourier transform 120. The results of this transformation are supplied to a parallel-to-serial converter 130, and the outgoing data stream is inserted with a cyclic prefix in a cyclic prefix block 140 to produce an OFDM signal, which is sent to radio frequency circuits.

FIG. 2 depicts an OFDM receiver, which receives a digital baseband signal such as that produced by the transmitter of FIG. 1. This input signal has a cyclic prefix removed by a cyclic prefix block 210. The resulting data stream is provided to a serial-to-parallel converter 220, which outputs to a Fourier transform 230. The results of this transformation are provided to an equalizer 240, and then to a phase compensator 250. The resulting data is passed through a parallel-to-serial converter 260 to provide an estimate of the original serial data stream corresponding with that depicted as input to the transmitter of FIG. 1.

A mathematical foundation is provided for OFDM systems in conjunction with FIGS. 1 and 2 to assist with later description of the implementation of techniques described herein.

In OFDM system, several input bits are first encoded into one symbol Xₖ, and then N symbols are grouped into one OFDM symbol and sent to the OFDM modulator. The OFDM modulator is implemented by using an inverse discrete Fourier Transform (IDFT). The modulated OFDM signal can be expressed as follows in Equation (1).

$${x}_{n} = ( 1 / N ) {\sum }_{k = 0}^{N - 1} {X}_{k} {ⅇ}^{j 2 π nk / N} ; n = 0 , 1 , 2 , … , N - 1. \qquad ( 1 )$$

After passing through a multipath frequency selective fading channel, the received OFDM signal can be written as expressed in Equation (2).

$${y}_{n} = ( 1 / N ) {\sum }_{k = 0}^{N - 1} {X}_{k} {H}_{k} {ⅇ}^{j 2 π t ( k + Δ ) / N} + {v}_{n} ; n = 0 , 1 , 2 , … , N - 1 , \qquad ( 2 )$$

In Equation (2), Hₖ is the channel transfer function at the frequency of the kth subcarrier, Δ is the relative frequency offset of the channel (the ratio of the actual frequency offset to the intercarrier spacing), and νₙ is the additive white Gaussian noise (AWGN). To recover the transmitted data, the demodulation process adopts FFT processing on the received signal. So the demodulated signal is as expressed in Equatior. (3).

$$\begin{matrix}{Y}_{k} = {\sum }_{n = 0}^{N - 1} {y}_{n} {ⅇ}^{- j 2 π n k / N} ; \\ = {X}_{k} {H}_{k} \frac{sin ( π Δ )}{N sin ( πΔ / N )} {ⅇ}^{j π Δ ( N - 1 ) / N} + {I}_{k} + {V}_{k} \\ k = 0 , 1 , 2 , … , N - 1.\end{matrix} \qquad ( 3 )$$

The first term of the series summation of Equation (3) is the desired signal at the kth subcarrier, which is attenuated by the channel response Hₖ and the frequency offset Δ. The second term, Iₖ, is the ICI caused by the frequency offset. Iₖ is derived as expressed in Equation (4).

$${I}_{k} = {\sum }_{{l \neq k}_{l = 0}}^{N - 1} {X}_{l} {H}_{l} \frac{sin ( π Δ )}{N sin [ π ( l - k + Δ ) / N ]} {ⅇ}^{j π Δ ( N - 1 ) / N} {ⅇ}^{- j x ( l - k ) / N} . \qquad ( 4 )$$

In the absence of frequency offset Δ, the demodulated signal can be simplified as expressed in Equation (5).

Yₖ=XₖHₖ+Vₖ. (5)

Generally, in order to obtain initial channel estimate, a training sequence, or a preamble, is transmitted first. For example, in the IEEE 802.11a standard for wireless LAN, two repeated OFDM symbols with a cyclic prefix, referred to as long training symbols, are transmitted for equalization purposes. During the training period, the training OFDM symbol is thus “known” to the receiver. The estimate of the channel response is obtained as expressed in Equation (6).

H′ₖ=Yₖ/Xₖ k=0,1, . . . ,N−1 (6)

In the IEEE 802.11a standard for wireless LAN, two repeated OFDM symbols with cyclic prefixes are used for channel estimation. Accordingly, a more accurate estimation of the channel can be obtained by taking the average of two estimations from the two training symbols.

For the data carrying symbols, the equalized symbol can be obtained as expressed in Equation (7).

X′ₖ=Yₖ·H′ₖ⁻¹ k=0,1, . . . ,N−1 (7)

Adverse Effects of Frequency Offset

Channel estimation, performed using the expression of Equation (6), is accurate when no frequency offset exists. Yet, some amount of frequency offset, however small, exists in all communication systems. Consequently, the channel estimation procedure according to Equation (6) becomes inaccurate since this procedure does not take into consideration ICI caused by the frequency offset. Other equalization procedures, such as those using least square (LS) and least mean squared (LMS) equalization algorithms, instead treat the ICI as intersymbol interference (ISI). Such algorithms cannot achieve a relatively high degree of accuracy, especially in burst communication systems, such as wireless LAN.

To reduce ICI and achieve more reliable communications, study and simulations indicate that frequency offset must be limited to less than 3% of the intercarrier spacing to maintain a signal-to-interference ratio 20 dB or greater. A relevant discussion is provided in Paul H Moose, “A Technique for Orthogonal Frequency Division Multiplexing Frequency Offset Correction”, IEEE Trans on Communications, Volume 42. No. 10, October 1994.

Consequently, a more accurate frequency extraction algorithm is required. Many, if not most, frequency estimation algorithms can achieve an accuracy of 3% or less of intercarrier spacing. However, the accuracy of the frequency estimation may often exceed 3%, and be perhaps up to 5% of the intercarrier spacing. This phenomenon is especially characteristic of systems that are required to operate within a relatively low SNR range. A loss of accuracy of this kind can degrade system performance significantly.

For example, in the IEEE 802.11a standard for wireless LAN, to achieve data rate of 54 Mbps, a 64 QAM modulation scheme is used for each subcarrier. The minimum angle between two 64 QAM constellation points is around 10°. Consequently, for demodulation, to maintain decision accuracy, phase rotation is desirably limited to ±5°.

If a frequency offset of 1% of the intercarrier spacing exists, phase rotation is ±3.6°. This phase rotation means that the frequency offset of more than 1.39% of the intercarrier spacing compromises the operation of the OFDM system.

The above illustrative description of undesirably rigorous frequency offset requirements in OFDM system does not consider the effect of a cyclic prefix. If considering the effect of a cyclic prefix, frequency offset requirements are even stricter.

In view of the above observations, a need clearly exists for improved techniques and arrangements for channel estimation and equalization in OFDM systems.

### SUMMARY

Iterative channel estimation and data equalization techniques are used to relax the frequency offset requirements in OFDM systems. An iterative procedure for estimating a channel response in an OFDM system assumes that an estimate of the frequency offset can be obtained.

An initial estimate of the channel response is first obtained, and the implied ICI is determined through calculation using the output from the FFT in an OFDM receiver. The channel response is iteratively re-estimated using this procedure, as often as required. In many cases, only one iteration is required.

Data equalization is performed using the channel response iteratively calculated as described. The implied ICI is constructed, and the output from the FFT in the OFDM receiver is adjusted to determine an estimate of transmitted OFDM data.

Accordingly, there is provided a method for channel estimation in a multicarrier modulation system, the method comprising the steps of:

calculating a initial estimate of a channel response of the multicarrier modulation system; and

calculating one or more iterations of the estimated intercarrier interference (ICI), by performing the steps of:

(i) determining a measure of intercarrier interference based on the calculated initial estimate of the channel response of the multicarrier modulation system;

(ii) subtracting a current estimate of the determined measure of intercarrier interference (ICI) from an output of a Fourier-based transform step performed in a receiver of the multicarrier modulation system, to produce an adjusted output of the Fourier-based transform step; and

(iii) updating the current estimate of the channel response of the multicarrier system by taking into account the adjusted output of the Fourier-based transform step.

Correspondingly, there is also provided a receiver for a multicarrier modulation system, the receiver comprising:

means for calculating an initial estimate of a channel response of the multicarrier modulation system; and

means for calculating one or more iterations of the estimated intercarrier interference (ICI) channel, to determine a measure of intercarrier interference based on the calculated initial estimate of the channel response of the multicarrier modulation system, to subtract a current estimate of the determined measure of intercarrier interference (ICI) from an output of a Fourier-based transform step performed in a receiver of the multicarrier modulation system, to produce an adjusted output of the Fourier-based transform step, and to update the current estimate of the channel response of the multicarrier system by taking into account the adjusted output of the Fourier-based transform step.

Computer software is also provided, suitable for performing channel estimation in a multicarrier modulation system, the computer software comprising:

code means for calculating an initial estimate of a channel response of the multicarrier modulation system; and

code means for calculating one or more iterations of the estimated intercarrier interference (ICI) channel, by performing the steps of:

(i) determining a measure of intercarrier interference based on the calculated initial estimate of the channel response of the multicarrier modulation system;

(ii) subtracting a current estimate of the determined measure of intercarrier interference (ICI) from an output of a Fourier-based transform step performed in a receiver of the multicarrier modulation system, to produce an adjusted output of the Fourier-based transform step; and

(iii) updating the current estimate of the channel response of the multicarrier system by taking into account the adjusted output of the Fourier-based transform step.

There is further provided a method for data equalization in a multicarrier modulation system, the method comprising the steps of:

calculating an initial estimate of transmitted data using an estimate of a channel response of the multicarrier modulation system;

determining a measure of intercarrier interference (ICI) implied by said initial estimate of the transmitted data;

adjusting output data from a Fourier-based transform step by subtracting the determined measure of intercarrier interference from the initial estimate of the transmitted data; and

equalizing the adjusted output data from the Fourier-based transform step using the estimate of the channel response.

A simplified implementation using the described techniques involves adjusting single tap equalizer values to provide an acceptable estimate of incoming data. In this respect, there is provided a method for channel estimation in a multicarrier modulation system, the method comprising the steps of:

determining single tap channel equalizer coefficients of an equalizer for a receiver of a multicarrier modulation system;

calculating intercarrier interference implied by determined single tap channel coefficients;

subtracting the calculated intercarrier interference (ICI) from an initial channel estimate; and

adjusting the single tap channel equalizer coefficients.

### DESCRIPTION OF DRAWINGS

FIGS. 1 and 2 are respective schematic representations of an OFDM transmitter and receiver in which techniques described herein relating to channel estimation and equalization can be implemented.

FIG. 3 is a schematic representation of a simplified iterative equalizer that operates in accordance with the techniques described herein.

FIG. 4 is a flowchart that represents steps involved in a channel estimation procedure described herein.

FIG. 5 is a flowchart that represents steps involved in a data equalization procedure described herein.

FIG. 6 is a flowchart that represents steps involved in a simplified channel equalization procedure described herein.

FIGS. 7 to 10 comprise a series of four performance graphs (of mean square error in dB against signal-to-noise ratio in dB) that represent the simulated results of an initial estimate and three subsequent iterations of an iterative equalizer constructed in accordance with the techniques described herein. A legend indicates results for different frequency offsets as a percentage on intercarrier frequency spacing.

FIGS. 11 to 16 comprise a series of six performance graphs (of mean square error in dB against signal-to-noise ratio in dB) that represent the simulated results of an iterative equalizer constructed in accordance with the techniques described herein. Each graph reflects the results of taking into account successively increasing numbers of neighbouring subcarriers. A legend indicates results for different frequency offsets as a percentage on intercarrier frequency spacing.

FIG. 17 is a schematic representation of a computer system suitable for performing the techniques described with reference to FIGS. 1 to 16.

### DETAILED DESCRIPTION

Improved techniques for estimating a channel response of multicarrier systems, and subsequently equalizing an incoming data stream in an appropriate manner, are described herein. Techniques that provide relative accuracy in determining frequency offset between transmitter and receiver provide a basis for the described techniques of channel estimation and data equalization.

Frequency Offset Estimation

According to the IEEE 802.11a standard, the whole preamble consists of 10 short slots (2 OFDM symbols' duration) and 2 long training OFDM symbols. Except for the use of automatic gain control (AGC), DC offset correction etc, a coarse frequency offset estimation is performed during the last 3 to 4 slots.

After the coarse frequency offset estimation, there is still some residual frequency offset left. Under the low SNR circumstance, the residual frequency offset will often exceed the requirement of 3% of the intercarrier spacing. A relatively fine frequency offset estimation is needed. Although the two repeated long training symbols are intended for the equalization, a fine frequency offset can be estimated as follows.

At the receiver, when the frequency offset is present with no AWGN, the first long training symbol is as expressed in Equation (8).

$${y}_{n} = ( 1 / N ) {\sum }_{k = 0}^{N - 1} {X}_{k} {H}_{k} {ⅇ}^{j 2 π n ( k + Δ ) / N} ; n = 0 , 1 , 2 , … , N - 1 \qquad ( 8 )$$

The second symbol is as expressed in Equation (9).

$${y}_{n + N} = {y}_{n} {ⅇ}^{j 2 π Δ} ; n = 0 , 1 , 2 , … , N - 1 \qquad ( 9 )$$

When the effects of AWGN noise are included, these expressions are respectively as expressed in Equations (10) and (11).

y₁ₙ=yₙ+ν₁ₙ; n=0,1,2, . . . , N−1 (10)

y₂ₙ=yₙe^{j2nΔ}+ν₂ₙ; n=0,1,2, . . . , N−1 (11)

A method likelihood estimate of the frequency offset is performed in the time domain, as expressed as in Equation (12).

$${Δ}^{′} \approx ( 1 / 2 π ) arg ( {\sum }_{n = 0}^{N - 1} {y}_{2 n} {y}_{1 n}^{*} ) . \qquad ( 12 )$$

The frequency offset can also be estimated in frequency domain. For a suitable analogous procedure, refer to any of the three publications listed below. The content of each of these three listed publications is hereby incorporated by reference.

Paul H Moose, “A Technique for Orthogonal Frequency Division Multiplexing Frequency Offset Correction”, IEEE Trans on Communications, Volume 42, No. 10, October 1994.

Centre for Wireless Communications, “OFDM Modem System Design Document”, 1999-Mocca-SRD-001C, 18 Jun. 1999.

J Li, G Liu, G B Giannakis, “Carrier Frequency Estimation for OFDM-Based WLANs”, IEEE Signal Processing Letters, Volume 18, No. 3, March 2001.

Iterative Estimation

The estimation algorithm is generalized by first multiplying a window function with the data sequence yₙ, before the received OFDM signal is output for FFT processing. The sequence {yₙwₙ} is output for FFT processing, in which {wₙ} is the existing window sequence. After FFT processing, the unequalized signal is expressed is in Equation (13).

$${Y}_{k} = {\sum }_{l = 0}^{N - 1} {X}_{l} {H}_{l} {W}_{k - l + Δ} + {U}_{k} k = 0 , 1 , … , N - 1 \qquad ( 13 )$$

In Equations (13) and (14), Wₖ represent the Fourier transform of the window sequence, and Uₖ is expressed as in Equation (14).

$${U}_{k} = {\sum }_{l = 0}^{N - 1} {V}_{l} {W}_{k - l + Δ} k = 0 , 1 , … , N - 1 \qquad ( 14 )$$

Assume that the expressions of Equation (15) apply, in which Y is the received data vector, X is the transmitted data vector, H is the channel response vector, and U is the noise vector respectively.

Y={Y_{0 Y}₁ . . . Y_{N-1}}^{T}

X={X_{0 X}₁ . . . X_{N-1}}^{T}

H={H_{0 H}₁ . . . H_{N-1}}^{T}

U={U_{0 U}₁ . . . U_{N-1}}^{T} (15)

A matrix of window coefficients is expressed in Equation (16) below.

$$W = [ \begin{matrix}{W}_{Δ} & {W}_{- 1 + Δ} & ⋯ & {W}_{- N + 1 + Δ} \\ {W}_{1 + Δ} & {W}_{Δ} & ⋯ & {W}_{- N + 2 + Δ} \\ ⋮ & ⋮ & ⋰ & ⋮ \\ {W}_{N - 1 + Δ} & {W}_{N - 2 + Δ} & ⋯ & {W}_{Δ}\end{matrix} ] \qquad ( 16 )$$

The output signal of the FFT can be expressed in a matrix form as indicated in Equation (17).

$$\begin{matrix}Y = W [ diag ( H ) ] X + U or \\ = W [ diag ( X ) ] H + U \\ = [ diag ( {W}_{Δ} , {W}_{Δ} , … , {W}_{Δ} ) ] [ diag ( H ) ] X + \\ [ W - diag ( {W}_{Δ} , {W}_{Δ} , … , {W}_{Δ} ) ] [ diag ( H ) ] X + U \\ = [ diag ( {W}_{Δ} , {W}_{Δ} , … , {W}_{Δ} ) ] [ diag ( H ) ] X + I + U\end{matrix} \qquad ( 17 )$$

In Equation (17), the first term is the desired signal and the second term is the ICI, which is expressed in Equation (18).

I=[W−diag(W_{Δ},W_{Δ}, - - - , W_{Δ})][diag(H)]X (18)

When the frequency offset equals zero, the matrix W reduces to an identity matrix. If a rectangular window is used, component W_{k+Δ} is the Dirichlet kernel Dₖ, as expressed in Equation (19). For further details concerning this expression, refer to Frederic J Harris “On the Use of Windows for Harmonic Analysis with the Discrete Fourier Transform”, Proceedings of the IEEE, Volume 66, No. 1, January 1978, the content of which is hereby incorporated by reference.

$${W}_{rect , k + Δ} = {D}_{k} = \frac{sin ( π Δ )}{N sin [ π ( k + Δ ) / N ]} \frac{exp ( j π Δ ( N - 1 ) / N )}{exp ( j π k / N )} \qquad ( 19 )$$

If frequency offset is estimated with relative accuracy as described herein, channel estimation and subsequent data equalization are desirably achieved as follows. First, an LS algorithm is used to obtain the expression of Equation (20). A suitable algorithm is described in O Edfors, M Sandell, J Van de Beek, S Wilson, P Borjesson, “OFDM Channel Estimation by Singular Value Decomposition”, IEEE Trans on Communications, Volume 46, No. 7, July 1998 the content of which is hereby incorporated by reference.

Z=W⁻¹Y=[diag(X)]H+W⁻¹U (20)

Second, during a training period, X is known a priori, and the channel response H can be estimated as per the expression of Equation (21).

H′=[diag(X)]⁻¹Z (21)

The equalized data for data equalization is, since H is estimated, as expressed in Equation (22).

X′≈[diag(H′)]⁻¹W⁻¹Y=X+[diag(H′)]⁻¹W⁻¹U (22)

Although this equalizer cancels the ICI, this equalizer requires the inverse of a matrix W and enhances noise U. This requirement makes the equalizer unnecessarily complex and reduces estimation accuracy. Accordingly, an iterative estimation scheme and data equalization scheme involve a series of steps as outlined in overview directly below.

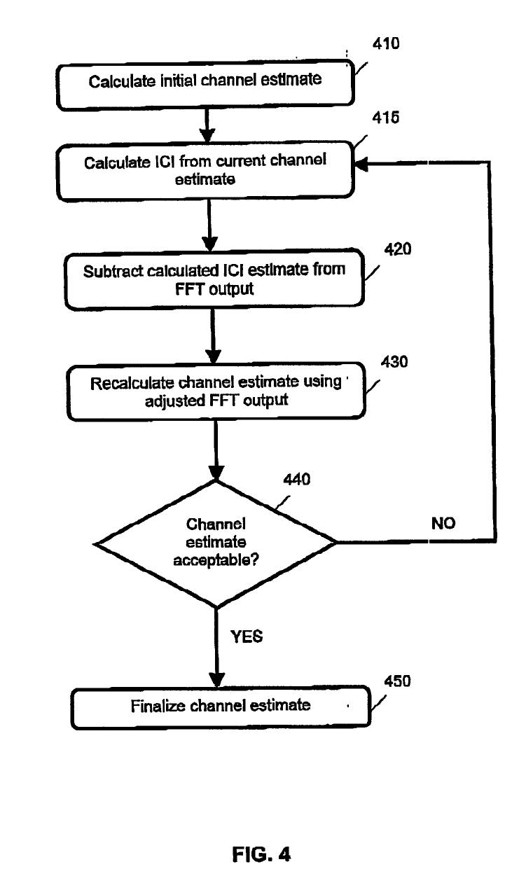

Channel estimation is performed with respect to steps indicated in FIG. 4, and described below.

Step 410 First, the initial channel estimation is obtained by Equation (21).

Step 415 From the output of FFT, Subtract the calculated ICI from Y.

Step 420 Calculate the ICI as: I=[W=diag(W_{Δ},W_{Δ}, . . . , W_{Δ})][diag(H′)]X.

Step 430 Re-estimate channel response H by H′=[diag(X)]⁻¹W⁻¹(Y−1).

Step 440 If the channel estimate is acceptable, proceed to step 450. Otherwise, processing returns to step 415.

Step 450 Finalize the channel estimate, if the estimate is acceptable.

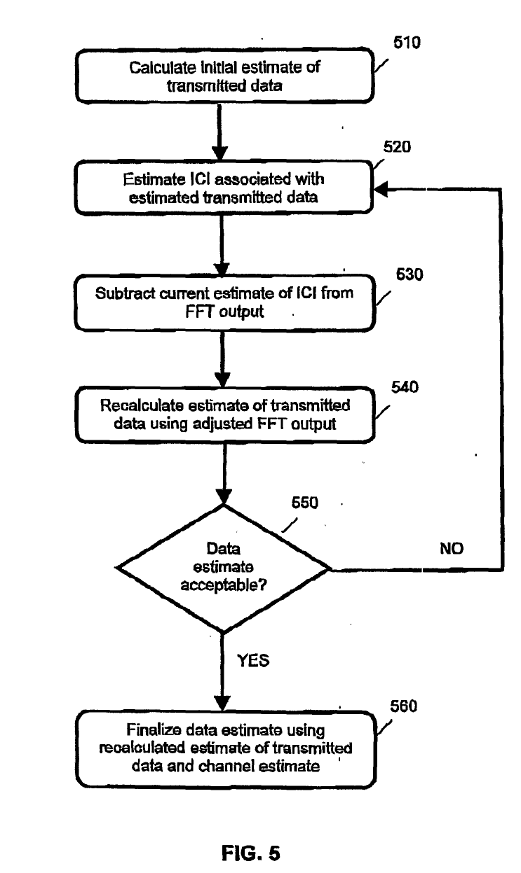

Data equalization is performed with respect to steps indicated in FIG. 5, and described below.

Step 510 Using the final channel estimate, determine an initial data estimate using Equation (22).

Step 520 Construct the ICI as: I=[W−diag(W_{Δ},W_{Δ}, . . . ,W_{Δ})][diag(H′)X′.

Step 530 From the output of FFT, subtract the ICI to get I′=Y−1.

Step 540 If the data estimate is acceptable, processing proceeds to step 550. Otherwise processing returns to step 520.

Step 550 The equalized data is obtained using X=[diag(W_{Δ},W_{Δ}, . . . ,W_{Δ})diag(H′)]⁻¹Y′.

Procedures for iterative channel estimation and data equalization, in accordance with the techniques described herein, can be relatively complicated and problematic to implement from a practical perspective. Accordingly, a simplified iterative equalizer is desirable, and is described directly below.

Simplified Iterative Channel Equalizer

To clearly illustrate the implementation of an iterative channel equalizer, a rectangular window is used as an example in the following description. Other windows, however, can be analogously used.

After FFT processing, the received signal can be rewritten as expressed in Equation (23).

$$\begin{matrix}{Y}_{k} = {X}_{k} {H}_{k} {W}_{Δ} + {\sum }_{l = 0 j \neq k}^{N - 1} {X}_{l} {H}_{l} {W}_{k - l + Δ} + {U}_{k} k = 0 , 1 , … , N - 1 \\ = {X}_{k} {H}_{k} {W}_{Δ} + {I}_{k} + {U}_{k}\end{matrix} \qquad ( 23 )$$

As ICI is generally much less than the desired signal, the initial channel estimation can be expressed as in Equation (24).

$${H}_{0 , k}^{′} = \frac{{Y}_{k}}{{X}_{k} {W}_{Δ}} = {H}_{k} + \frac{{I}_{k}}{{X}_{k} {W}_{Δ}} + \frac{{U}_{k}}{{X}_{k} {W}_{Δ}} \qquad ( 24 )$$

If H′_{n,k} is known for Hₖ, ICI can be calculated approximately, where the index n denotes the nth iteration. An expression for this approximate ICI is given as Equation (25).

$${I}_{n , k} = {\sum }_{l = 0 j \neq k}^{N - 1} {X}_{l} {H}_{n , l}^{′} {W}_{k - l + Δ} k = 0 , 1 , … , N - 1 \qquad ( 25 )$$

A more accurate estimation for Hₖ is obtained by the iterative equation of Equation (26).

$${H}_{n + 1 , k}^{′} = {H}_{0 , k}^{′} - {α}_{n} \frac{{I}_{n , k}}{{X}_{k} {W}_{Δ}} \qquad ( 26 )$$

In Equation (26), αₙ is step size. If the estimated I_{n,k} is close to the real ICI Iₖ, the step size is expected to be close to one. The optimal step size can be obtained by minimising the mean square error ∥H′ₙ−H∥² as expressed in Equation (27).

$${‖ {H}_{n}^{′} - H ‖}^{2} ≡ {‖ {H}_{0}^{′} - {α}_{n} \frac{{I}_{n}}{{XW}_{Δ}} - H ‖}^{2} \qquad ( 27 )$$

From derivation, minimising ∥H′ₙ−H∥² is equivalent to minimising ∥I−αₙIₙ∥. So the optimal step size can be approximated, as expressed in Equation (28).

$${α}_{n , opt} = \frac{{\sum }_{k = 0}^{N - 1} {I}_{k} {I}_{n , k}^{*}}{{\sum }_{k = 0}^{N - 1} {I}_{n , k} {I}_{n , k}^{2}} \qquad ( 28 )$$

However, the above theoretical value depends on the real ICI, which is difficult to estimate. Simulations indicate that αₒₚₜ is typically between 0.8 to 1.0. Generally, using 0.8 produces satisfactory results.

The simplified iterative equalizer described above is still relatively complex to implement. This complexity arises as reconstructing the ICI includes iterative channel estimation and multiplication operations involving channel response, window function and data, and consumes significant amounts of memory. To further reduce the complexity of the iterative equalizer, the following factors can be taken into account.

The number of iterations performed can be set to only one. This means that after initial estimation n=0, only n=1 channel estimation iteration is performed. In theory, more iterations improve estimation accuracy. However, after the first iteration, most of the ICI is cancelled, and subsequent iterations cancel diminishing amounts of residual ICI. Consequently, performing only one iteration after the initial estimate produces a satisfactory improvement.

On the other hand, compare the ICI expressions expressed in Equation (4) with those of Equation (29).

$$\begin{matrix}{I}_{k} = {\sum }_{{l = 0}_{l \neq k}}^{N - 1} {X}_{l} {H}_{l} \frac{sin ( π Δ )}{N sin [ π ( l - k + Δ ) / N ]} {ⅇ}^{j π Δ ( N - 1 ) / N} {ⅇ}^{- j π ( l - k ) / N} \\ = {\sum }_{{l = 0}_{l \neq k}}^{N - 1} {X}_{l} {H}_{l} \frac{sin ( π Δ )}{N sin ( πΔ / N )} {ⅇ}^{j π Δ ( N - 1 ) / N} \frac{sin ( π Δ / N )}{ sin [ π ( l - k + Δ ) / N ]} {ⅇ}^{- j π ( l - k ) / N}\end{matrix} \qquad ( 29 )$$

Usually, after the coarse frequency offset estimation and correction, the residual frequency offset is reduced to 5% of the intercarrier spacing or less, so the ICI is much smaller than the desired signal in the equation (3). Hence, the ICI can be approximated as expressed in Equation (30).

$$\begin{matrix}{I}_{k} \approx {\sum }_{{l = 0}_{l \neq k}}^{N - 1} {Y}_{l} \frac{sin ( π Δ / N )}{ sin [ π ( l - k + Δ ) / N ]} {ⅇ}^{- j π ( l - k ) / N} \approx {\sum }_{l = k}^{N - 1} {Y}_{l} \frac{π Δ}{N sin [ π ( l - k ) / N ]} {ⅇ}^{- j π ( l - k ) / N} \\ = Δ {\sum }_{{l = 0}_{l \neq k}}^{N - 1} {Y}_{l} \frac{π }{N sin [ π ( l - k ) / N ]} {ⅇ}^{- j π ( l - k ) / N} \\ = Δ {\sum }_{{l = 0}_{l \neq k}}^{N - 1} {Y}_{l} {C}_{1 - k} k = 0 , 1 , … , N - 1\end{matrix} \qquad ( 30 )$$

From Equation (30), the reconstructed and simplified ICI does not require channel estimation, and only one set of predetermined constants {C_{-N+1}, . . . ,C₋₂,C₋₁,C₁,C₂, . . . ,C_{N-1}} is stored in memory. Equation (30) is available for both channel estimation and data equalization. Accordingly, the iterative equalizer is simplified considerably.

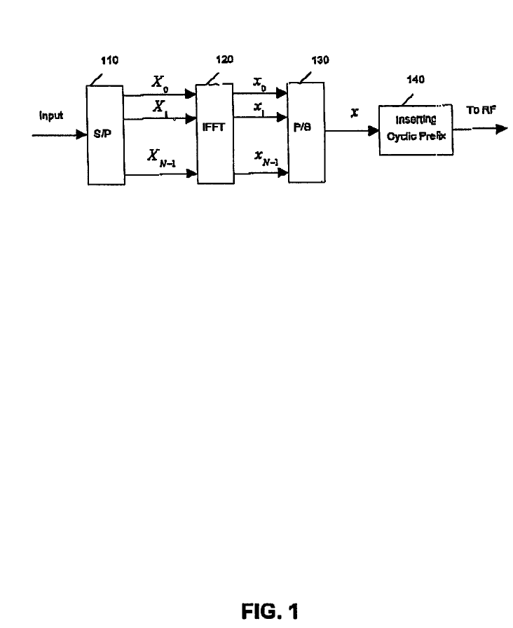

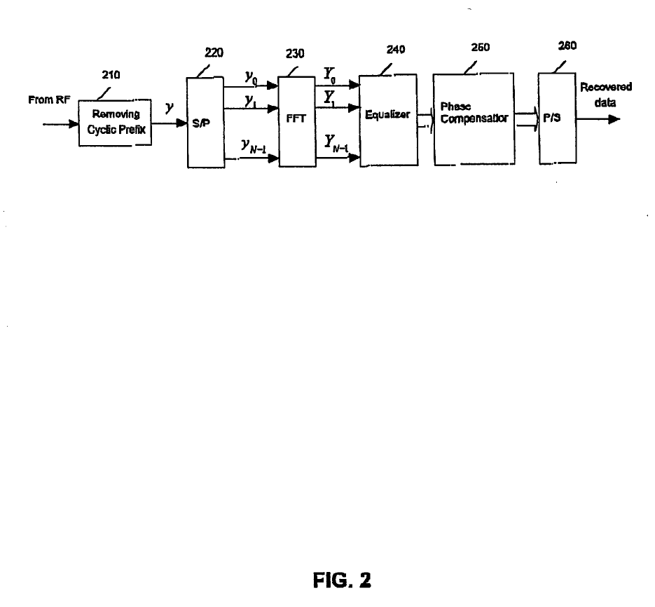

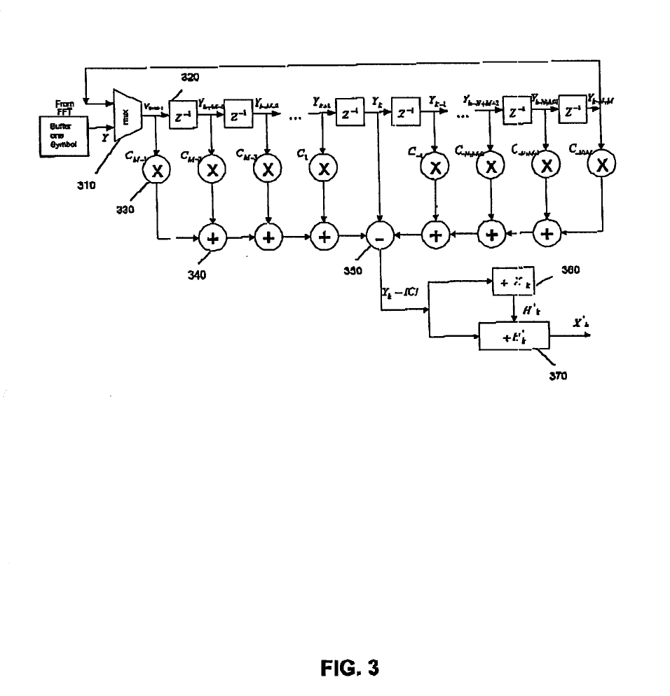

FIGS. 1 and 2 generically depict the transmitter and receiver in which the techniques described herein are desirably implemented. FIG. 3 schematically represents an implementation of the simplified iterative equalizer in accordance with the described techniques. This iterative equalizer of FIG. 3 can be used as the equalizer 240 represented in the OFDM receiver of FIG. 2.

The simplified iterative equalizer in FIG. 3 is implemented with a finite impulse response (FIR) structure, in which data is input to a time-based multiplexer 310, and subsequently delayed through a series of delay stages 320, each of which is labelled Z⁻¹. The input data is, at each delay stage, multiplicatively convolved with C data, as represented by multiplication blocks 330. The results are progressively summed using summation blocks 340, and a difference calculated on either side of the “centre” datum Yₖ using difference block 350. The output is an estimate of Yₖ less ICI.

During a training period, the estimate of Yₖ less ICI (Yₖ−ICI) is sent to a divider 360 and divided by known stored training data (Xₖ) to estimate the channel response Hₖ. Then, while the data is transmitted, the Yₖ−ICI is sent to another divider 370 and divided by the estimated Hₖ to obtain an estimate of transmitted data. Since the two divisions are not performed simultaneously, in practical implementations of the simplified equalizer, only one divider is needed for the channel estimation and data equalization

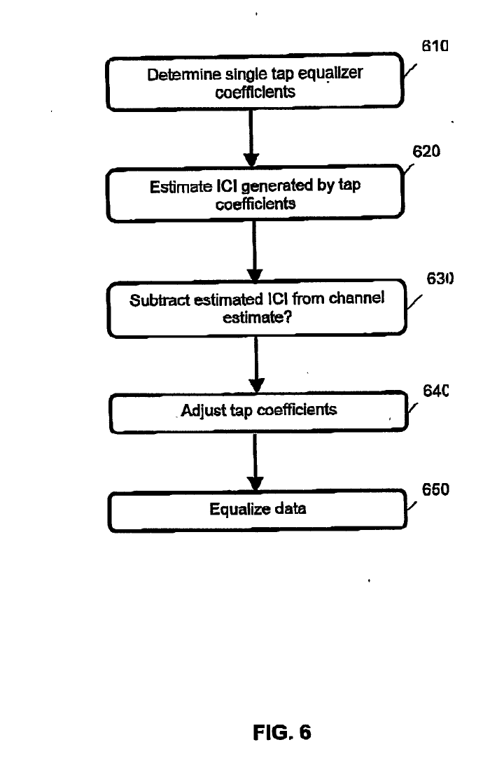

FIG. 6 is a flowchart describing steps involved in simplified data equalization. In step 610, a determination is made of single tap equalizer coefficients. In step 620, an estimate is made of ICI implied by these determined tap equalizer coefficients.

As described with reference to Equation (4), the ICI of an individual subcarrier is caused by a summation of interference from all other subcarriers, and the envelope of the interference decays according to the Dirichlet kernel rule, as per Equation (19). Accordingly, ICI power leaks mainly from nearby subcarriers.

So, in reconstructing the ICI, the summation of interference from all (N−1) subcarriers can be reduced to 2L neighbouring subcarriers, in which 2L is less than (N−1). For L=5, the neighbouring 10 subcarriers can be calculated to contribute 89% of the total interference power. For L=9, the neighbouring 18 subcarriers can be calculated to contribute 94% of the total interference power. When L is limited to 9 or less, the iterative equalizer can be further simplified.

Simulation Results

In each simulation, the MSE of the estimated channel response is plotted over E_{b}/N₀ for relative frequency offsets Δ={0.01, 0.05, 0.1, 0.2}. The MSE is defined as expressed in Equation (31).

$$MSE = \frac{{‖ {H}^{′} - H ‖}^{2}}{{‖ H ‖}^{2}} . \qquad ( 31 )$$

For all simulations, 16-QAM modulation is used. The channel is modelled as a multipath Rayleigh fading channel. The multipath channel is implemented as a FIR filter with six equidistant taps spaced by 12.5 ns. An exponential power delay profile is used. The delay spread of the channel is τ_{RMS}=20 ns, and the Doppler frequency is 17.5 Hz.

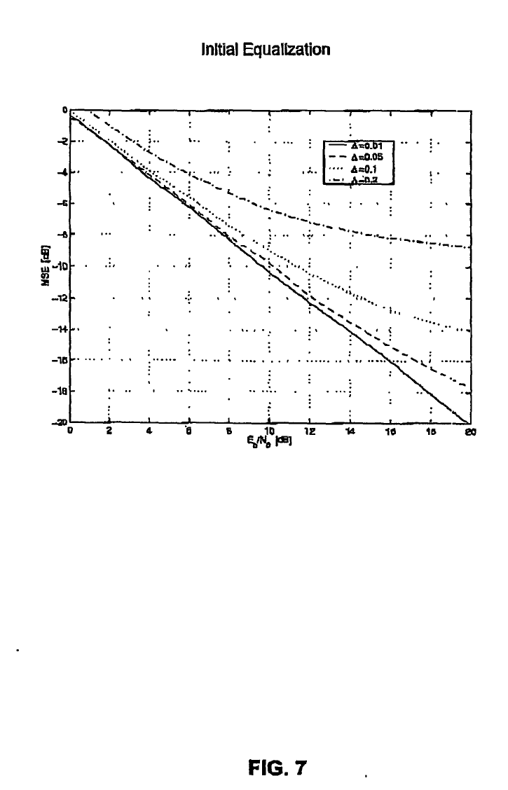

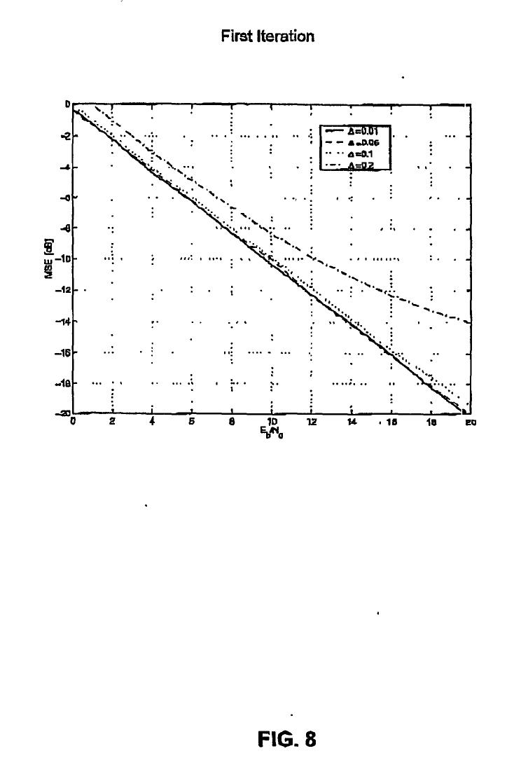

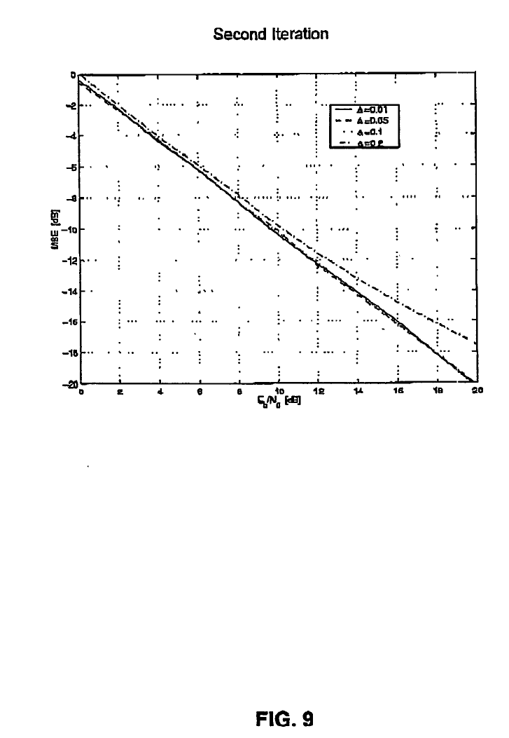

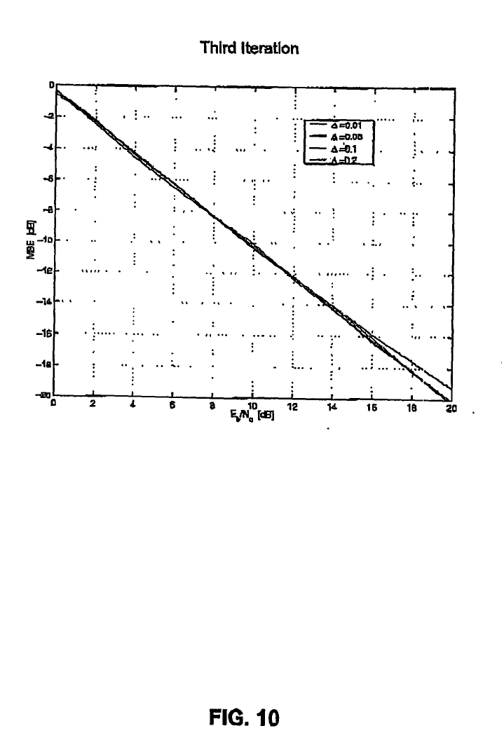

FIGS. 7 to 10 are graphs that respectively depict simulation results of the iterative equaliser with all interference subcarriers for an initial and three successive iterations. The MSE improves with each iteration. After the initial estimation, the first iteration improves the estimation. The amount of improvement achieved decreases with each subsequent iteration that is performed. Performing only one iteration for the equalizer estimation offers a satisfactory balance between equalizer complexity and accuracy in many cases.

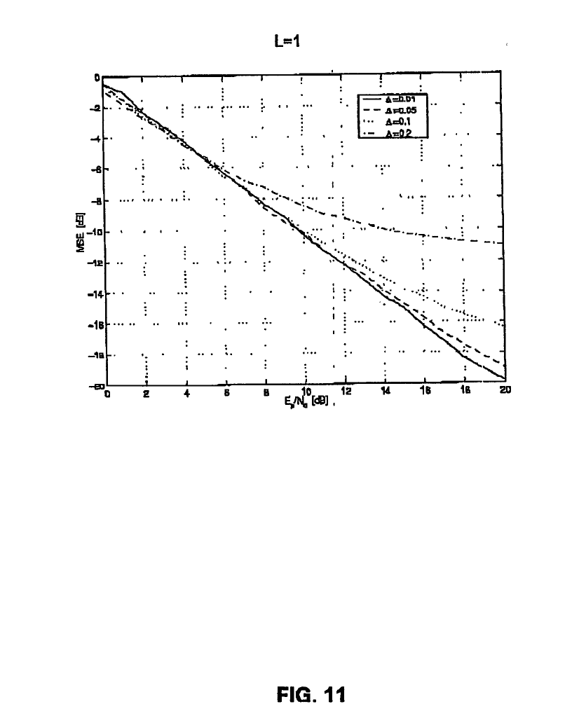

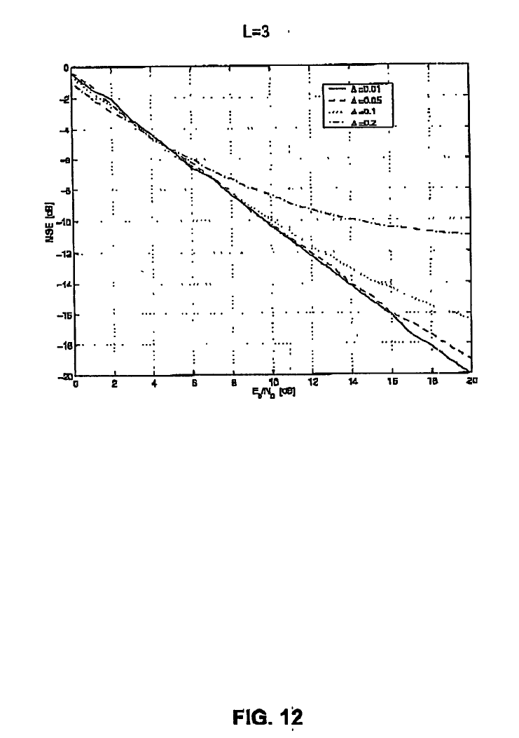

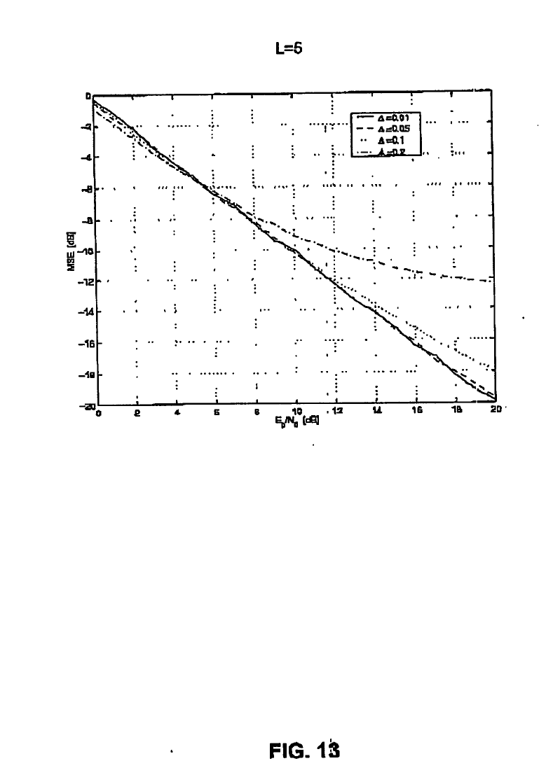

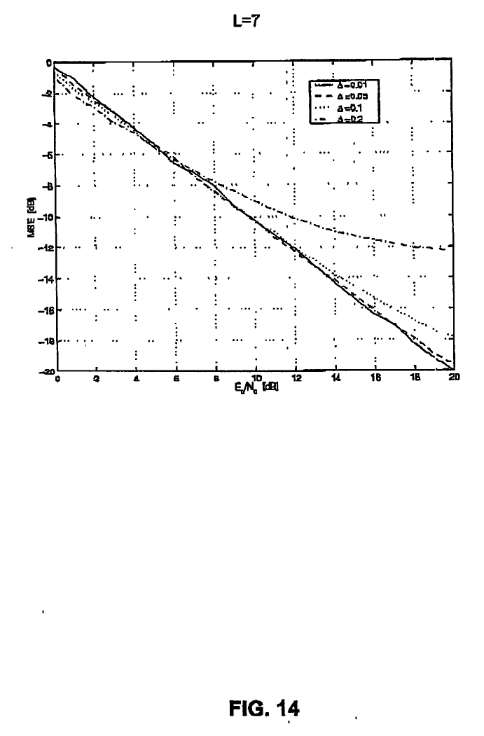

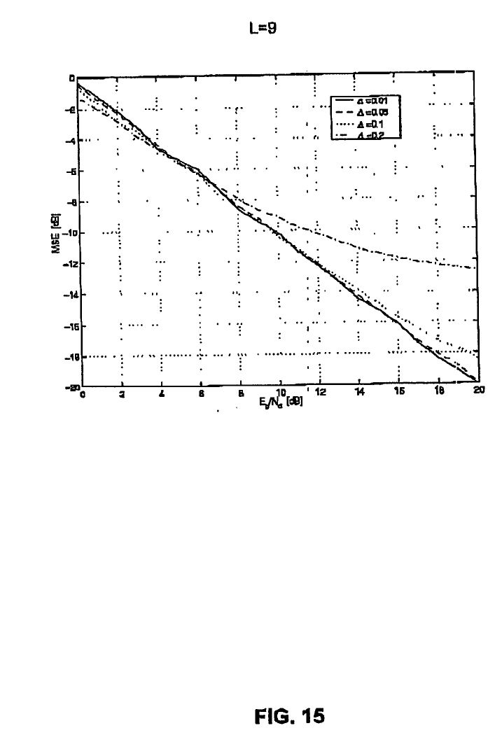

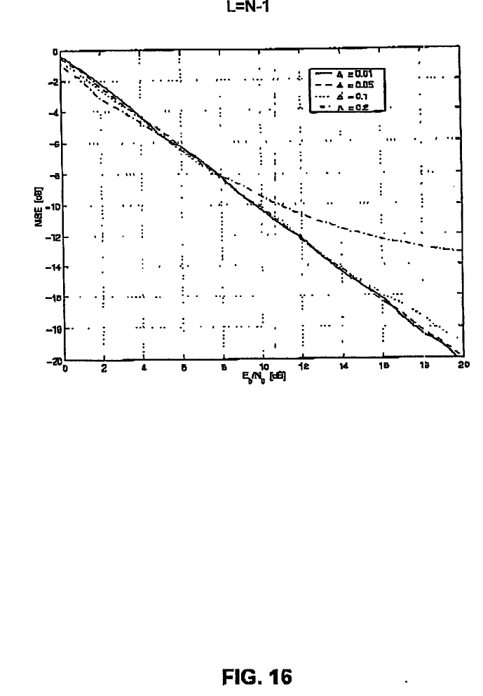

FIGS. 11 to 16 graphically represent the simulated results of an iterative equaliser in accordance with FIG. 3, at the first iteration with different constraint lengths. With a constraint length of L=9, the achieved MSE is relatively close to that achieved as if the length is maximum (N−2). This observation implies that the complexity can consequently be reduced in this manner with acceptable results.

Computer Hardware and Software

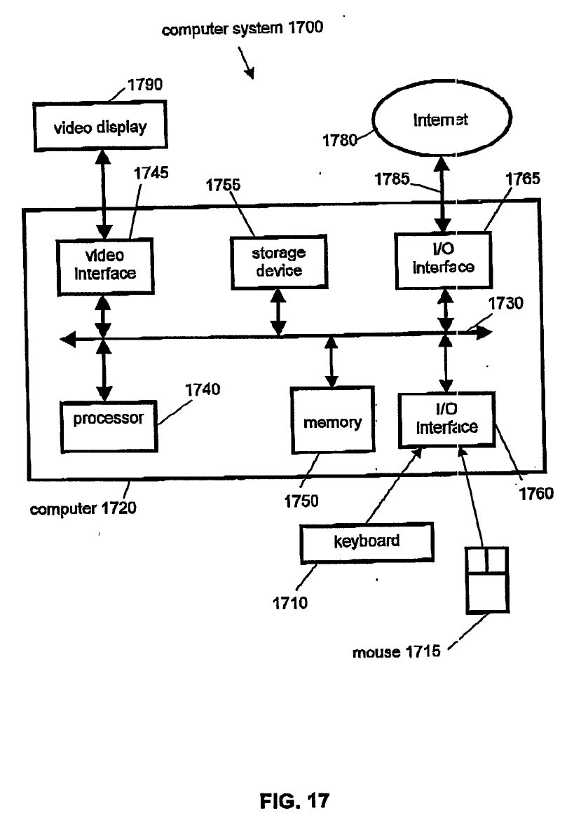

FIG. 17 is a schematic representation of a computer system 1700 that can be used to perform steps in a process that implement the techniques described herein. Simulation programs can be executed, and simulation results obtained using such a computer system 1700. This computer software executes under a suitable operating system installed on the computer system 1700.

The computer software involves a set of programmed logic instructions that are able to be interpreted by the computer system 1700 for instructing the computer system 1700 to perform predetermined functions specified by those instructions. The computer software can be an expression recorded in any language, code or notation, comprising a set of instructions intended to cause a compatible information processing system to perform particular functions, either directly or after conversion to another language, code or notation.

The computer software is programmed by a computer program comprising statements in an appropriate computer language. The computer program is processed using a compiler into computer software that has a binary format suitable for execution by the operating system. The computer software is programmed in a manner that involves various software components, or code means, that perform particular steps in the process of the described techniques.

The components of the computer system 1700 include: a computer 1720, input devices 1710, 1715 and video display 1790. The computer 1720 includes: processor 1740, memory module 1750, input/output (I/O) interfaces 1760, 1765, video interface 1745, and storage device 1755.

The processor 1740 is a central processing unit (CPU) that executes the operating system and the computer software executing under the operating system. The memory module 1750 includes random access memory (RAM) and read-only memory (ROM), and is used under direction of the processor 1740.

The video interface 1745 is connected to video display 1790 and provides video signals for display on the video display 1790. User input to operate the computer 1720 is provided from input devices 1710, 1715 consisting of keyboard 1710 and mouse 1715. The storage device 1755 can include a disk drive or any other suitable non-volatile storage medium.

Each of the components of the computer 1720 is connected to a bus 1730 that includes data, address, and control buses, to allow these components to communicate with each other via the bus 1730.

The computer system 1700 can be connected to one or more other similar computers via a input/output (I/O) interface 1765 using a communication channel 1785 to a network 1780, represented as the Internet.

The computer software program may be provided as a computer program product, and recorded on a portable storage medium. In this case, the computer software program is accessed by the computer system 1700 from the storage device 1755. Alternatively, the computer software can be accessed directly from the network 1780 by the computer 1720. In either case, a user can interact with the computer system 1700 using the keyboard 1710 and mouse 1715 to operate the programmed computer software executing on the computer 1720.

The computer system 1700 is described for illustrative purposes: other configurations or types of computer systems can be equally well used to implement the described techniques. The foregoing is only an example of a particular type of computer system suitable for implementing the described techniques.

A receiver in an OFDM system uses similar digital hardware to perform the calculations described herein. The digital hardware may execute computer software that instructs the hardware to perform relevant instructions. Certain calculations may be performed directly by dedicated hardware rather than by general-purpose hardware.

Conclusion

A method, a computer system and computer software are described herein in the context of channel estimation and equalization for ODFM systems, in which an iterative procedure can be used to improve the accuracy of channel estimation and equalization procedures.

The described iterative channel estimator can be used to reduce the ICI in OFDM signals. With the iterative equalizer, the OFDM systems can relax accuracy requirements for frequency offset estimation. Consequently, the described iterative equalizer can be used to improve the performance of OFDM systems, especially when high level modulation schemes are adopted in OFDM systems, such as 16 QAM, 64 QAM etc. The complexity of the described iterative equalizer can be reduced significantly using the described FIR filter structure.

Various alterations and modifications can be made to the techniques and arrangements described herein, as would be apparent to one skilled in the relevant art.

1. A method for channel estimation in a multicarrier modulation system, the method comprising the steps of:
calculating an initial estimate of a channel response of the multicarrier modulation system; and
calculating one or more iterations of the estimated intercarrier interference (ICI), by performing the steps of:
(i) determining a measure of intercarrier interference based on the calculated initial estimate of the channel response of the multicarrier modulation system;
(ii) subtracting a current estimate of the determined measure of intercarrier interference (ICI) from an output of a transform step performed in a receiver of the multicarrier modulation system, to produce an adjusted output of the transform step; and
(iii) updating the current estimate of the channel response of the multicarrier system by taking into account the adjusted output of the transform step.

2. The method as claimed in claim 1, wherein a finite number of adjacent subcarriers are used to perform step (i).

3. The method as claimed in claim 1, wherein only one iteration is performed of said calculated estimates of intercarrier interferences according to steps (i) to (iii).

4. The method as claimed in claim 1, wherein the multicarrier modulation system is an orthogonal frequency division multiplexing system.

5. The method as claimed in claim 4, wherein the transform step involves the use of a Fourier-based transform.

6. A receiver for a multicarrier modulation system, the receiver comprising:
means for calculating an initial estimate of a channel response of the multicarrier modulation system; and
means for calculating one or more iterations of the estimated intercarrier interference (ICI) channel, to determine a measure of intercarrier interference based on the calculated initial estimate of the channel response of the multicarrier modulation system, to subtract a current estimate of the determined measure of intercarrier interference (ICI) from an output of a transform step performed in a receiver of the multicarrier modulation system, to produce an adjusted output of the transform step, and to update the current estimate of the channel response of the multicarrier system by taking into account the adjusted output of the transform step.

7. Computer software suitable for performing channel estimation in a multicarrier modulation system, the computer software comprising:
code means for calculating an initial estimate of a channel response of the multicarrier modulation system; and
code means for calculating one or more iterations of the estimate intercarrier interference (ICI) channel, by performing the steps of:
(i) determining a measure of intercarrier interference based on the calculated initial estimate of the channel response of the multicarrier modulation system;
(ii) subtracting a current estimate of the determined measure of intercarrier interference (ICI) from an output of a transform step performed in a receiver of the multicarrier modulation system, to produce an adjusted output of the transform step; and
(iii) updating the current estimate of the channel response of the multicarrier system by taking into account the adjusted output of the transform step.

8. A method for data equalization in a multicarrier modulation system, the method comprising the steps of:
calculating an initial estimate of transmitted data using an estimate of a channel response of the multicarrier modulation system;
determining a measure of intercarrier interference (ICI) implied by said initial estimate of the transmitted data;
adjusting output data from a transform step by subtracting the determined measure of intercarrier interference from the initial estimate of the transmitted data; and
equalizing the adjusted output data from the transform step using the estimate of the channel response.

9. A method for channel estimation in a multicarrier modulation system, the method comprising the steps of:
determining single tap channel equalizer coefficients of an equalizer for a receiver of a multicarrier modulation system;
calculating intercarrier interference implied by the determined single tap channel coefficients;
subtracting the calculated intercarrier interference (ICI) from an initial channel estimate; and
adjusting the single tap channel equalizer coefficients.

10. The method as claimed in claim 7 or 8, wherein the implied intercarrier interference (ICI) is calculated using a FIR filter structure available for both channel estimation and data equalization.
